(19) United States
(12) Patent Application Publication
(10) Pub. No.: US 2024/0310445 A1
(43) Pub. Date: Sep. 19, 2024

(54) LITHIUM-ION BATTERY DIAGNOSTIC

(71) Applicant: GM Global Technology Operations LLC, Detroit, MI (US)

(72) Inventors: Yue-Yun Wang, Troy, MI (US); Jian Gao, Auburn Hills, MI (US); Shengbing Jiang, Rochester Hills, MI (US)

(21) Appl. No.: 18/185,482

(22) Filed: Mar. 17, 2023

(51) Int. Cl. G01R 31/367; G01R 31/392; H01M 10/0525; H01M 50/204; H01M 50/51

(52) U.S. Cl. CPC G01R 31/367; G01R 31/392; H01M 10/0525; H01M 50/204; H01M 50/51; H01M 2220/20

(57) ABSTRACT

A Thevenin equivalent model of a lithium-ion battery cell provides the basis for a simplified cell diagnostic relying on cell current and cell terminal voltage measurements.

### INTRODUCTION

The subject disclosure relates to electrified vehicles (EV). More particularly, the subject disclosure relates to lithium-ion battery systems in an EV.

During lithium-ion cell formation, a passivation layer (i.e., an initial solid electrolyte interphase (SEI) layer) is carefully formed on the cell electrodes, mainly the anode. Initial SEI layer thickness may range from a few nanometers to a few tens of nanometers. As a lithium-ion cell ages, the SEI layer tends to thicken due to ongoing electrolyte decomposition and the deposition of reaction products, which can reduce the cell's performance and cycle life. Typical end-of-life SEI thicknesses can range from several tens to several hundreds of nanometers. During service life, general or localized excessive SEI layer thickening and anode cracking may cause issues including localized heating, decomposition of electrode material, lithium plating and dendrite growth including through the battery separator material and bridging (i.e., internal shorting) of the electrodes. Undesirable thermal events in a lithium-ion cell due to local heating and/or bridging may cause destruction of the cell and destruction of adjacent cells in a battery pack. Thus, it is desirable to diagnose abnormal or accelerated growth of the SEI layer and develop an early understanding of cell degradation in a lithium-ion battery and provide intervention opportunities.

### SUMMARY

In one exemplary embodiment, a method of determining a state-of-health of each cell in a lithium-ion battery pack of multiple (n) cells may include modeling each of the multiple (n) cells in accordance with a relationship V_{T,i}=a_{0,i}−a_{1,i}\dot{V}_{T,i}+a_{2,i}İ_{b}+a_{3,i}I_{b} for i=1 to n wherein V_{T,i} is a terminal voltage of the ith cell. \dot{V}_{T,i} is a time derivative of the terminal voltage of the ith cell, I_{b} is a current through the ith cell, İ_{b} is a time derivative of the current through the ith cell, a_{0,i} is V_{oc,i}, wherein V_{oc,i} is an open circuit voltage of a Thevenin equivalent of the ith cell, a_{1,i} is R_{1,i}C_{1,i}, wherein R_{1,i} is a charge transfer resistance of the Thevenin equivalent of the ith cell and C_{1,i} is a capacitance of the Thevenin equivalent of the ith cell in parallel with R_{1,i}, a_{2,i} is R_{O,i}R_{1,i}C_{1,i}, wherein R_{O,i} is an internal resistance of the Thevenin equivalent of the ith cell, and a_{3,i} is R_{O,i}+R_{1,i} for the ith cell. The method may include periodically measuring V_{T,i} and Ip for each of the multiple (n) cells, estimating \dot{V}_{T,i} and İ_{b} based on V_{T,i} and I_{b} for each of the multiple (n) cells, estimating a_{0,i}, a_{1,i}, a_{2,i} and a_{3,i} for each of the multiple (n) cells based on the relationship V_{T,i}=a_{0,i}−a_{1,i}\dot{V}_{T,i}+a_{2,i}İ_{b}+a_{3,i}I_{b}, determining if a_{1,i} for each of the multiple (n) cells exceeds a first predetermined threshold, and diagnosing an unacceptable solid electrolyte interphase (SEI) layer state-of-health for the ith cell when a_{1,i} for the ith cell exceeds the first predetermined threshold.

In addition to one or more of the features described herein, the first predetermined threshold may include a calibration value.

In addition to one or more of the features described herein, the first predetermined threshold may include a value based upon the respective a_{1,i} from a subset of the multiple (n) cells excluding the ith cell.

In addition to one or more of the features described herein, the method may further include diagnosing an unacceptable internal resistance state-of-health for the respective cell when a_{1,i} does not exceed the first predetermined threshold and a_{2,i} exceeds a second predetermined threshold.

In addition to one or more of the features described herein, the method may further include diagnosing an unacceptable internal resistance state-of-health for the respective cell when a_{1,i} does not exceed the first predetermined threshold and a_{3,i} exceeds a third predetermined threshold.

In addition to one or more of the features described herein, the method may further include diagnosing an unacceptable internal resistance state-of-health for the respective cell when a_{1,i} does not exceed the first predetermined threshold, a₂ exceeds a second predetermined threshold and a_{3,i} exceeds a third predetermined threshold.

In addition to one or more of the features described herein, wherein the method may be carried out under a constant current constraint and further include diagnosing an unacceptable cell capacitance state-of-health for the respective cell when a_{3,i} does not exceed a third predetermined threshold.

In addition to one or more of the features described herein, wherein the method may be carried out under a constant current constraint and further include diagnosing an unacceptable charge transfer resistance state-of-health for the respective cell when a_{3,i} exceeds a third predetermined threshold.

In addition to one or more of the features described herein, wherein the method may be carried out under a zero current constraint.

In addition to one or more of the features described herein, wherein the constant current constraint may include a constant charge current.

In addition to one or more of the features described herein, wherein the constant current constraint may include a constant charge current.

In addition to one or more of the features described herein, wherein estimating a_{0,i}, a_{1,i}, a_{2,i} and a_{3,i} for each of the multiple (n) cells based on the relationship V_{T,i}=a_{0,i}−a_{1,i}\dot{V}_{T,i}+a_{2,i}İ_{b}+a_{3,i}I_{b} may include performing a recursive least squares estimation.

In another exemplary embodiment, a method of determining a state-of-health of each cell in a lithium-ion battery pack of multiple (n) cells connected in series may include monitoring a current through the battery pack, monitoring a respective terminal voltage across each cell, determining a rate of change of the current, when the rate of change of the current exceeds a predetermined rate of change threshold and the current exceeds a predetermined current threshold, determining for each cell a ratio of a) the product of the current over a time interval and the time interval to b) a change in the respective terminal voltage over the time interval, determining if the ratio for each cell exceeds a predetermined ratio threshold, and diagnosing an unacceptable solid electrolyte interphase (SEI) layer state-of-health for one respective cell when the ratio for the one respective cell exceeds the predetermined threshold.

In addition to one or more of the features described herein, the predetermined threshold may include a calibration value.

In addition to one or more of the features described herein, the predetermined threshold may include a value based upon the respective ratios from a subset of the multiple (n) cells excluding the one respective cell.

In yet another exemplary embodiment, a method of determining a state-of-health of each cell in a lithium-ion battery pack of multiple (n) cells connected in series may include monitoring current through the battery pack, monitoring a respective terminal voltage across each cell, monitoring a respective open circuit voltage for each cell, and when the battery pack is in a relaxation period after a charging period wherein the relaxation period includes zero current through the battery pack, determining for each of the multiple (n) cells a respective time rate of change of the respective terminal voltage, determining for each of the multiple (n) cells a respective voltage difference between the respective open circuit voltage and respective terminal voltage, determining a respective time constant for each of the multiple (n) cells as a ratio of the respective voltage difference and the respective time rate of change, determining if the respective time constant for each of the multiple (n) cells exceeds a predetermined time constant threshold, and diagnosing an unacceptable solid electrolyte interphase (SEI) layer state-of-health for one respective cell when the respective time constant for the one respective cell exceeds the predetermined time constant threshold.

In addition to one or more of the features described herein, the predetermined threshold may include a calibration value.

In addition to one or more of the features described herein, the predetermined threshold may include a value based upon the respective ratios from a subset of the multiple (n) cells excluding the one respective cell.

In addition to one or more of the features described herein, the method may be carried out during a vehicle drive cycle.

In addition to one or more of the features described herein, the charging period may include a regenerative braking period.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 schematically illustrates an embodiment of an exemplary electric propulsion system on an electrified vehicle, in accordance with one or more embodiments;

FIG. 2 illustrates an exemplary Thevenin equivalent of a lithium-ion cell, in accordance with one or more embodiments;

FIG. 3 illustrates an exemplary direct current (DC) fast charge (FC) profile used in recharging an electric vehicle battery pack cell, in accordance with one or more embodiments;

FIG. 4 illustrates an exemplary end-of-charge profile for a vehicle battery pack cell, in accordance with one or more embodiments;

FIG. 5 illustrates an exemplary plot of cell current versus time in an operational electric vehicle during a typical drive cycle, in accordance with one or more embodiments;

FIG. 6 illustrates an exemplary plot of cell current rate of change versus time in an operational electric vehicle during a typical drive cycle corresponding to the exemplary plot of cell current versus time of FIG. 5, in accordance with one or more embodiments;

FIG. 7 illustrates relative magnitude of capacitance change ΔC for a plurality of cells, in accordance with one or more embodiments;

FIG. 8 illustrates an exemplary plot of cell current versus time in an operational electric vehicle during a typical drive cycle, in accordance with one or more embodiments; and

FIG. 9 illustrates an exemplary plot of voltage versus time in an operational electric vehicle during a typical drive cycle corresponding to the exemplary plot of cell current versus time of FIG. 8, in accordance with one or more embodiments.

### DETAILED DESCRIPTION

The following description is merely exemplary in nature and is not intended to limit the present disclosure, its application or uses. Throughout the drawings, corresponding reference numerals indicate like or corresponding parts and features.

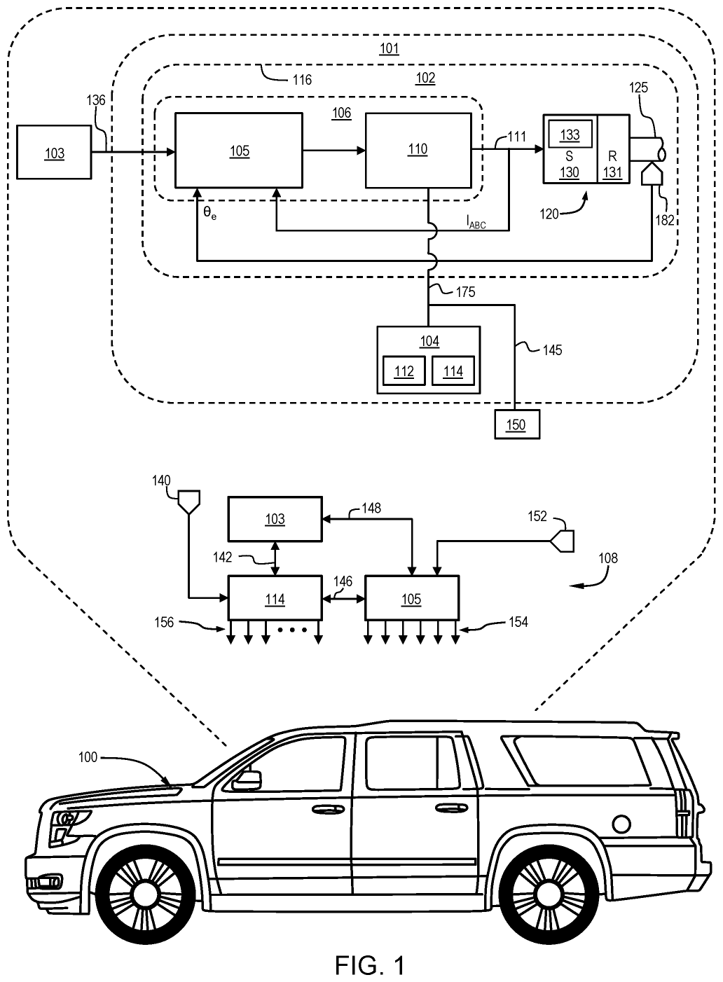

FIG. 1 schematically illustrates an embodiment of an exemplary electric propulsion system 101 on an electrified vehicle 100. Vehicle and vehicular are understood to refer to any means of transportation including non-limiting examples of motorcycles, cars, trucks, buses, excavation, earth moving, construction and farming equipment, railed vehicles like trains and trams, aircraft, and watercraft like ships and boats. The electric propulsion system 101 may include various control components and electrical and electro-mechanical systems including, for example, a rechargeable energy storage system (RESS) 104 and at least one electric drive unit (EDU) 102. The electric propulsion system 101 may be employed in a powertrain system to generate propulsion torque as a replacement for, or in conjunction with, an internal combustion engine in various electric vehicle (EV) applications and hybrid electric vehicle (HEV) applications, respectively.

The EDU 102 may be of varying complexity, componentry, integration and power capabilities. The EDU 102 may include, for example, an alternating current (AC) motor (motor) 120 and a traction power inverter module (TPIM) 106 including a motor controller 105 and a power inverter 110 which may be contained within or integrated with an EDU housing 116. The motor 120 may include a stator 130 (S) including stator winding 133 and a rotor 131 (R) coupled to a rotor shaft 125 and a position sensor 182, for example a resolver or an encoder. The position sensor 182 may signally connect directly to the motor controller 105 and is employed to monitor angular position of the rotor (0e) of the motor 120. The angular position of the rotor (De) of the motor 120 is employed by the motor controller 105 to control operation of the power inverter 110 that controls the motor 120.

The rotor shaft 125 may transfer torque between the motor 120 and driveline components (not illustrated) at a drive end, for example a final drive which may include reduction and differential gear sets and one or more axle outputs. The final drive may simply include reduction gearing and a prop shaft output coupling to a differential gear set. One or more axles may couple to the final drive or differential gear sets if separate therefrom. Axle(s) may couple to a vehicle wheel(s) for transferring tractive force between a wheel and pavement. One having ordinary skill in the art will recognize alternative arrangements for driveline components. Propulsion torque requests or commands 136 (T_{cmd}) may be provided by a vehicle controller 103 to the motor controller 105 of the TPIM 106 of EDU 102.

In an embodiment, the RESS 104 may include one or more electro-chemical battery packs 112, for example high capacity, high voltage (HV) rechargeable lithium ion battery packs for providing power to the vehicle via a HV direct current (DC) bus 175. An accessory bus 145 may couple to the HV DC bus 175 for providing electrical energy to high voltage accessory loads 150 such as an auxiliary power module (e.g., a power converter to step down higher voltages to lower voltages), an air conditioning electronic compressor and a battery pack heater. The RESS 104 may also include a battery manager module 114. The RESS 104 battery packs 112 may be constructed from a plurality of battery pack modules allowing for flexibility in configurations and adaptation to application requirements. Battery packs may include a plurality of battery pack modules constructed from a plurality of cells allowing for flexibility in configurations and adaptation to application requirements. Battery pack modules may include a plurality of cells allowing for flexibility in configurations and adaptation to application requirements. For example, in vehicular uses, the battery packs 112 and battery pack modules may be modular to the extent that their numbers and configurations may be varied to accommodate a desired energy density or range objective of a particular vehicle platform, intended use, or cost target and in accordance with propulsion and charging functions and flexibility. Selective reconfiguration of the battery packs 112 and the battery pack modules may be by way of controllable switches for opening and closing various electrical paths effective to provide various parallel and series configurations of the battery packs 112 and the battery pack modules. The switches may be implemented as ultra-low voltage drop solid state devices such as MOS controlled thyristors (MCTs), GaN field effect transistors (FETs), SiC junction field effect transistors (JFETs), metal-oxide-semiconductor field-effect transistors (MOSFETs), insulated-gate bipolar transistors (IGBTs) or other low loss devices of suitable voltage and current ratings. The switches may also be implemented using electromechanical relays (EMRs) or a combination of EMRs in parallel with solid state devices to further reduce the on-state conduction losses wherein the solid state device carries the current during switching from on-to-off or off-to-on state of the electromechanical relay to eliminate arcing. The RESS 104 may include a plurality of battery packs 112 each having a nominal battery pack voltage of, for example, 400 volts or 800 volts and being configured in parallel in respective 400 volt or 800 volt propulsion architectures during propulsion and during direct current fast charging (DCFC). The battery packs 112 may also be selectively coupled to the HV DC bus 175 and to charge ports by way of switches. Some or all such switches may be integrated into one or more controllable battery disconnect units (BDU) (not illustrated) or distributed variously within components or subsystems such as the RESS 104. It is understood that the RESS 104 may be reconfigurable at any level of integration including battery pack, battery module and cell levels.

The motor 120 may be a poly-phase AC motor receiving poly-phase AC power over a poly-phase motor control power bus (AC bus) 111 which is coupled to the power inverter 110. In one embodiment, the motor 120 is a three-phase motor and the power inverter 110 is a three-phase power inverter. The power inverter 110 may include a plurality of solid-state switches based on IGBT and power MOSFET devices, for example. The power inverter 110 may couple to DC power provided by the HV DC bus 175 from the RESS 104. The HV DC bus may couple to the power inverter 110, the accessory bus 145 and to other high voltage loads including additional power converters (not illustrated). The motor controller 105 is coupled to the power inverter 110 for control thereof. The power inverter 110 electrically connects to stator phase windings of a poly-phase stator winding of the motor 120 via the AC bus 111, with electric current monitored on two or three of the phase leads thereof. The power inverter 110 is configured with suitable control circuits including paired power transistors for transforming high-voltage DC electric power to high-voltage AC electric power and transforming high-voltage AC electric power to high-voltage DC electric power. The power inverter 110 may employ pulse width modulation (PWM) control to convert stored DC electric power originating in the battery packs 112 of the RESS 104 to AC electric power to drive the motor 120 to generate torque. Similarly, the power inverter 110 may convert mechanical power transferred to the motor 120 to DC electric power to generate electric energy that is storable in the battery packs 112 of the RESS 104, including as part of a regenerative control strategy. The power inverter 110 may be configured to receive motor control commands from motor controller 105 and control power inverter states to provide the motor drive and regeneration functionality.

Control of the power inverter 110 may include high frequency switching of the solid-state switches in accordance with a PWM control. A number of design and application considerations and limitations determine inverter switching frequency and PWM control. Inverter controls for AC motor applications may include fixed switching frequencies, for example switching frequencies around 10-20 kHz and PWM controls that minimize switching losses of the solid-state switches of the power inverter 110.

The electric propulsion system 101 on the vehicle 100 may include a control system 108 including one or more electronic control units (ECU), for example the vehicle controller 103, the battery manager module 114, and the motor controller 105. The control system 108 may be responsible for carrying out functions related to the propulsion system 101 monitoring, control and diagnostics, including RESS charge control or supervision, based upon a plurality of inputs. The vehicle controller 103 may include one or more ECUs and may be responsible for supervising, interpreting various user and environmental inputs, information arbitration, and issuing and receiving control commands and requests to and from various other ECUs, including the battery manager module 114 and the motor controller 105 as illustrated by communication lines 142, 146 and 148. The battery manager module 114 may include one or more ECUs and may receive a plurality of inputs 140 related to the RESS 104 including, for example, voltage, current and temperature at cell, module, pack and RESS levels at various module and pack configurations, and may determine state of charge (SOC), depth of discharge (DOD) state of health (SOH) and other metrics at cell, module, pack and RESS levels at various module and pack configurations. The battery manager module 114 may also communicate with charging infrastructure through charge port control pilot and proximity pilot communications. The battery manager module 114 may be responsible for charge and discharge control, monitoring and diagnostics of the RESS 104, and selective reconfiguration of the RESS through control of a plurality of switches by issuing switch state commands 156 to the switches. The individual state commands may be issued in the form of binary state signals (e.g., 1=on/closed, 0=off/open) from the battery manager module 114. The motor controller 105 may include one or more ECUs and may receive various inputs 152 used in the monitoring, control and diagnosis of the motor 120 and power inverter 110, including phase currents I_{ABC} from respective current sensors and rotor position information from the position sensor 182. The motor controller 105 may control the motor 120 by issuing conduction commands 154 to the power inverter solid-state switches. The individual conduction commands may be issued in the form of PWM signals from the motor controller 105. Any suitable solid-state device may be employed as the inverter solid-state switches including, for example, solid-state relays and transistors such as Si IGBTs, Si MOSFETs, SiC MOSFETs, GaN high-electron-mobility transistor (HEMT), SiC JFETs, Diamond, Gallium Oxide and other Wide Band Gap (WBG) semiconductor-based power switch devices. Each power inverter solid-state switch may also have an associated anti-parallel diode either as a discrete component or integrated with each solid-state switch. In accordance with one embodiment, the battery manager module 114 may be responsible for monitoring and diagnosis of the RESS 104, for discharge and charge control including during propulsion operation and for electric power transfers from and to off-vehicle power sources, including infrastructure chargers and other vehicles.

The control system 108, including the vehicle controller 103, the battery manager module 114, and the motor controller 105, may include one or more ECUs. As used herein, ECU, control module, module, control, controller, control unit, electronic control unit, processor and similar terms mean any one or various combinations of one or more of Application Specific Integrated Circuit(s) (ASIC), electronic circuit(s), central processing unit(s) (preferably microprocessor(s)) and associated memory and storage (read only memory (ROM), random access memory (RAM), electrically programmable read only memory (EPROM), hard drive, etc.) or microcontrollers executing one or more software or firmware programs or routines, combinational logic circuit(s), input/output circuitry and devices (I/O) and appropriate signal conditioning and buffer circuitry, high speed clock, analog to digital (A/D) and digital to analog (D/A) circuitry and other components to provide the described functionality. A control module may include a variety of communication interfaces including point-to-point or discrete lines and wired or wireless interfaces to networks including wide and local area networks, and in-plant and service-related networks including for over the air (OTA) software updates. Functions of a control module as set forth in this disclosure may be performed in a distributed control architecture among several networked control modules. Software, firmware, programs, instructions, routines, code, algorithms and similar terms mean any controller executable instruction sets including calibrations, data structures, and look-up tables. A control module may have a set of control routines executed to provide described functions. Routines are executed, such as by a central processing unit, and are operable to monitor inputs from sensing devices and other networked control modules and execute control and diagnostic routines to control operation of actuators. Routines may be executed at regular intervals during ongoing engine and vehicle operation. Alternatively, routines may be executed in response to occurrence of an event, software calls, or on demand via user interface inputs or requests.

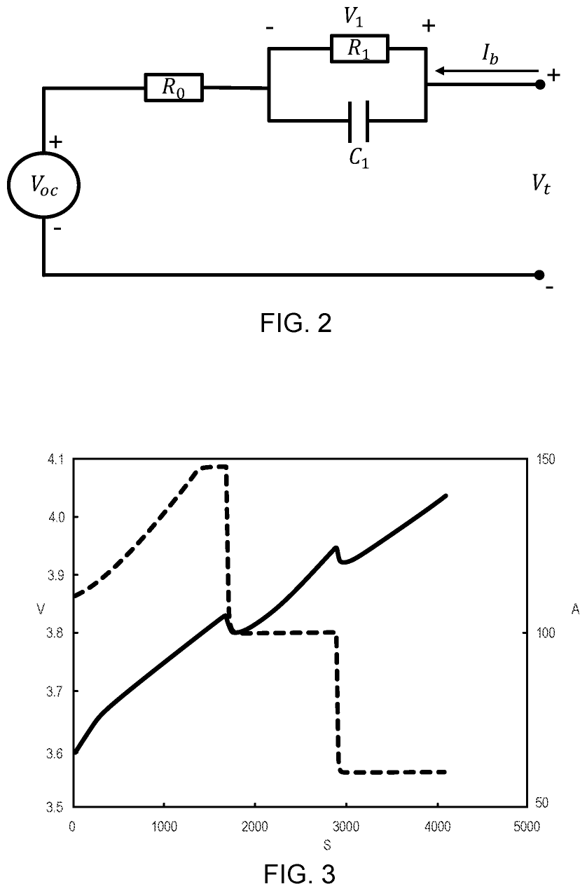

Equivalent circuit models of lithium-ion batteries are known and used in developmental modeling and simulation as well as in practical applications, for example by the battery manager module 114 to monitor and control the RESS 104. Equivalent circuit models are generally cell level models. One such model is a simplified Thevenin equivalent which may be useful in characterizing time variant performance of a battery. The Thevenin equivalent includes a parallel resistor-capacitor (RC) network in series with the battery internal resistance, thus describing certain dynamic characteristics of the battery. As shown in FIG. 2, such a cell model may include three main parts including an open-circuit voltage V_{OC}, an internal ohmic resistance R_{O} and a parallel RC network of R₁ and C₁. The capacitance C₁ and resistance R₁ describe the transient response during charging and discharging. V₁ is the voltages across parallel RC network. I_{b} is the current through the cell with charging being positive and discharging being negative. The electrical behavior of the Thevenin equivalent may be expressed by the following Thevenin equivalent model equations:

$${V}_{T} = {V}_{OC} + {R}_{O} {I}_{b} + {V}_{1} \qquad [ 1 ]$$

$${\dot{V}}_{1} = - \frac{{V}_{1}}{{R}_{1} {C}_{1}} + \frac{{I}_{b}}{{C}_{1}} \qquad [ 2 ]$$

$$τ = {R}_{1} {C}_{1} = \frac{- {V}_{1} + {R}_{1} {I}_{b}}{{\dot{V}}_{1}} = \frac{- ( {V}_{T} - {V}_{OC} - {R}_{O} {I}_{b} ) + {R}_{1} {I}_{b}}{{\dot{V}}_{1}} = \frac{{V}_{OC} - {V}_{T} + {R}_{O} {I}_{b} + {R}_{1} {I}_{b}}{{\dot{V}}_{1}} \qquad [ 3 ]$$

wherein V_{T} is the terminal voltage of the cell;
V_{OC} is the open circuit voltage of the cell;
R_{O} is the internal resistance of the cell;
I_{b} is the current through the cell;
V₁ is the voltage across the parallel R₁C₁ network;
\dot{V}₁ is the time derivative of the voltage across the parallel R₁C₁ network;
R₁ is the charge transfer resistance of the cell;
C₁ is the capacitance of the cell; and
R₁C₁ is the time constant t of the cell.
   In the equations herein, derivative quantities may be designated using the dot notation (e.g., \dot{V}₁) or standard notation (e.g.,

$$\frac{{d V}_{1}}{dt} ) ,$$

the notation used being based solely on convenience and ease of equation manipulation as will be appreciated.

V_{T} and I_{b} may be known from direct measurements and V_{OC} may be estimated, for example. In accordance with an embodiment, monitoring of the time constant τ=R₁C₁ associated with the Thevenin model provides insight into potential undesirable battery conditions. The time constant may represent the combined double SEI layers (anode and cathode) and the charge transfer electrochemical process associated with the SEI. If the time constant becomes larger (i.e., increases in R₁ or C₁), then a slower voltage response to charge and discharge currents is present and may indicate SEI layer growth and potentially associated lithium plating and/or dendrite growth. More particularly, increasing cell capacitance may correlate to SEI surface area growth, whereas increasing cell charge transfer resistance may correlate to thickening of the SEI layer.

A rearrangement of equation [2] yields equation [2.1]

$$τ {\dot{V}}_{1} = {R}_{1} {C}_{1} {\dot{V}}_{1} = - {V}_{1} + {R}_{1} {I}_{b} \qquad [ 2.1 ]$$

Taking derivatives of equation [1] yields equation [1.1].

$${\dot{V}}_{T} = {\dot{V}}_{OC} + {R}_{O} {\dot{I}}_{b} + {\dot{V}}_{1} \qquad [ 1.1 ]$$

Because open circuit voltage changes very slowly (i.e., \dot{V}_{OC}<<\dot{V}₁ and \dot{V}_{OC}<<\dot{V}_{T}), \dot{V}_{OC} is negligible and equation [1.1] is closely approximated by equation [1.2].

$${\dot{V}}_{T} = {R}_{O} {\dot{I}}_{b} + {\dot{V}}_{1} \qquad [ 1.2 ]$$

Substituting \dot{V}₁ from equation [1.2] into equation [2.1] yields equation [2.2].

$$τ ( {\dot{V}}_{T} - {R}_{O} {\dot{I}}_{b} ) = - {V}_{1} + {R}_{1} {I}_{b} \qquad [ 2.2 ]$$

Substituting V₁ from equation [1] into equation [2.2] yields equation [2.3].

$$τ ( {\dot{V}}_{T} - {R}_{O} {\dot{I}}_{b} ) = - {V}_{T} + {V}_{OC} + {R}_{O} {I}_{b} + {R}_{1} {I}_{b} \qquad [ 2.3 ]$$

Distributing t and rearranging equation [2.3] for V_{T} yields equation [2.4].

$${V}_{T} = {V}_{OC} - τ {\dot{V}}_{T} + τ {R}_{O} {\dot{I}}_{b} + ( {R}_{O} + {R}_{1} ) {I}_{b} \qquad [ 2.4 ]$$

V_{T}, I_{b}, \dot{V}_{T} and İ_{b} are known from direct measurement and calculations. Equation [2.4] may be recast as a first order differential equation [2.5].

$${V}_{T} = {a}_{0} - {a}_{1} {\dot{V}}_{T} + {a}_{2} {\dot{I}}_{b} + {a}_{3} {I}_{b} \qquad [ 2.5 ]$$

$$wherein$$

$${a}_{0} = {V}_{oc} ,$$

$${a}_{1} = τ = {R}_{1} {C}_{1} ,$$

$${a}_{2} = τ {R}_{O} = {R}_{1} {C}_{1} {R}_{O} ,$$

$$and$$

$${a}_{3} = ( {R}_{O} + {R}_{1} ) .$$

Coefficients a₀, a₁, a₂ and a₃ may be solved, for example using a recursive least square to estimate a₀, a₁, a₂ and a₃. Advantageously, in certain situations and under certain conditions, the charge transfer resistance of the cell R₁, the capacitance of the cell C₁, and the internal resistance of the cell R_{O} may be isolated from the regressed coefficients a₀, a₁, a₂ and a₃ and may be useful in more granular diagnostics. Advantageously, and under constant current conditions, the equation [2.5] may be simplified as equation [2.6] leaving only coefficients a₀, a₁ and a₃ to solve as follows.

$${V}_{T} = {a}_{0} - {a}_{1} {\dot{V}}_{T} + {a}_{3} {I}_{b} \qquad [ 2.6 ]$$

Advantageously, and under zero current conditions, the equation [2.5] may be simplified as equation [2.7] leaving only coefficients a₀ and a₁ to solve as follows.

$${V}_{T} = {a}_{0} - {a}_{1} {\dot{V}}_{T} \qquad [ 2.7 ]$$

In accordance with an embodiment, monitoring of the time constant t=R₁C₁ associated with the Thevenin model provides insight into potential undesirable battery conditions. The time constant may represent the combined double SEI layers (anode and cathode) and the charge transfer electrochemical process associated with the SEI. If the time constant becomes larger (i.e., increases in R₁ or C₁), then a slower voltage response to charge and discharge currents is present and may indicate SEI layer growth and potentially associated lithium plating and/or dendrite growth. More particularly, increasing cell capacitance may correlate to SEI surface area growth whereas increasing cell charge transfer resistance may correlate to thickening of the SEI layer.

In an embodiment, a lithium-ion battery pack may include multiple (n) cells connected in series. Each of the of the multiple (n) cells may be modeled in accordance with equation [2.5] V_{T,i}=a_{0,i}−a_{1,i}\dot{V}_{T,i}+a_{2,i}İ_{b}+a_{3,i}I_{b} including the subscripted i designation where i=1 to n. Advantageously, readily accessible voltage and current measurements, V_{T,i} and I_{b}, for the terminal voltages and the cell currents may provide the only parameters necessary for estimating the coefficients a₀, a₁, a₂ and a₃. In an embodiment, V_{T,i} and I_{b}, are periodically measured for each cell and their first derivatives, \dot{V}_{T,i} and İ_{b}, are estimated. Coefficients a_{0,i}, a_{1,i}, a_{2,i} and a_{3,i} of equation [2.5] V_{T,i}=a_{0,i}−a_{1,i}\dot{V}_{T,i}+a_{2,i}İₚ+a_{3,i}I_{b} are estimated, for example from a recursive least squares estimation. Each of the respective cell's coefficient a_{1,i} (i.e., τ=R₁C₁) is compared with a first predetermined threshold. When the first predetermined threshold is exceeded, an unacceptable solid electrolyte interphase (SEI) layer state-of-health for the corresponding cell may be determined. From this information, the time constant τ=R₁C₁ of the corresponding cell is determined to correlate to an unacceptable solid electrolyte interphase (SEI) layer state-of-health.

In an embodiment, when the first predetermined threshold is exceeded by a respective cell's coefficient a_{1,i}, a_{2,i} (i.e., τR_{O}=R₁C₁R_{O}) exceeds a second predetermined threshold, and a_{3,i} (i.e., (R_{O}+R₁)) exceeds a third predetermined threshold, an unacceptable charge transfer resistance R₁ state-of-health for the corresponding cell may be determined. Similarly, in an embodiment, when the first predetermined threshold is exceeded by a respective cell's coefficient a_{1,i}, a_{2,i} (i.e., τR_{O}=R₁C₁R_{O}) exceeds a second predetermined threshold, yet a_{3,i} (i.e., (R_{O}+R₁)) does not exceed a third predetermined threshold, an unacceptable cell capacitance C₁ state-of-health for the corresponding cell may be determined. Advantageously, a respective cell's coefficients a_{1,i}, a_{2,i} and a_{3,i} may effectively decouple or isolate the charge transfer resistance R₁ and the cell capacitance C₁ of the cell from the cell's time constant τ=R₁C₁ under certain conditions.

In an embodiment, the first, second and third predetermined thresholds may simply be calibration values. In an embodiment, the calibration values may be adapted throughout the life cycle of the battery pack to track normal SEI layer growth or battery aging, for example to prevent undesirable false positive diagnosis. In an embodiment, the first predetermined threshold may be a value based upon the respective coefficients a_{1,i} from a subset of the multiple (n) cells excluding the coefficient a_{1,i} from the cell presently being diagnosed. For example, a statistical representation of the coefficients a_{1,i} from such a subset may be used as the first predetermined threshold. Similarly, the second predetermined threshold may be a value based upon the respective coefficients a_{2,i} from a subset of the multiple (n) cells excluding the coefficient a_{2,i} from the cell presently being diagnosed. For example, a statistical representation of the coefficients a_{2,i} from such a subset may be used as the second predetermined threshold. Similarly, the third predetermined threshold may be a value based upon the respective coefficients a_{3,i} from a subset of the multiple (n) cells excluding the coefficient a_{3,i} from the cell presently being diagnosed. For example, a statistical representation of the coefficients a_{3,i} from such a subset may be used as the third predetermined threshold. Such statistical representations may take the form of a simple mean or median value or more sophisticated representations based on data distributions, probabilistic models and regressed data. For example, the first, second and third predetermined thresholds may be represented as some multiple of a standard deviation of the respective coefficients a_{1,i}, a_{2,i}, a_{3,i} from the respective subsets of the multiple (n) cells excluding the coefficient a_{1,i}, a_{2,i}, a_{3,i} from the cell presently being diagnosed.

In an embodiment, when the first predetermined threshold is not exceeded by a respective cell's coefficient a_{1,i}, yet a_{2,i} (i.e., τR_{O}=R₁C₁R_{O}) exceeds a second predetermined threshold, an unacceptable internal resistance R_{O} state-of-health for the corresponding cell may be determined. Advantageously, a respective cell's coefficients a_{1,i} and a_{2,i} may effectively decouple or isolate the internal resistance R_{O} of the cell from the cell's time constant τ=R₁C₁ under certain conditions.

In an embodiment, when the first predetermined threshold is not exceeded by a respective cell's coefficient a_{1,i}, yet a_{2,i} (i.e., τR_{O}=R₁C₁R_{O}) exceeds a second predetermined threshold, and yet a_{3,i} (i.e., (R_{O}+R₁)) exceeds a third predetermined threshold, an unacceptable internal resistance R_{O} state-of-health for the corresponding cell may be determined. Advantageously, a respective cell's coefficients a_{1,i}, a_{2,i} and a_{3,i} may effectively decouple or isolate the internal resistance R_{O} of the cell from the cell's time constant τ=R₁C₁ under certain conditions.

In an embodiment, when the first predetermined threshold is not exceeded by a respective cell's coefficient a_{1,i}, yet a_{3,i} (i.e., (R_{O}+R₁)) exceeds a third predetermined threshold, an unacceptable internal resistance R_{O} state-of-health for the corresponding cell may be determined. Advantageously, a respective cell's coefficients a_{1,i} and a_{3,i} may effectively decouple or isolate the internal resistance R_{O} of the cell from the cell's time constant τ=R₁C₁ under certain conditions.

In an embodiment, cell currents/b may be constant. When the first predetermined threshold is exceeded by a respective cell's coefficient a_{1,i}, yet a_{3,i} (i.e., (R_{O}+R₁)) does not exceed a third predetermined threshold, an unacceptable cell capacitance C₁ state-of-health for the corresponding cell may be determined. In an embodiment, the constant cell currents may be constant charge currents, for example during a controlled charge routine through a vehicle charge port. Advantageously, a respective cell's coefficients a_{1,i} and a_{3,i} may effectively decouple or isolate the capacitance C₁ of the cell from the cell's time constant τ=R₁C₁ under certain conditions.

In an embodiment, cell currents/p may be constant. When the first predetermined threshold is exceeded by a respective cell's coefficient a_{1,i}, and a_{3,i} (i.e., (R_{O}+R₁)) also exceeds a third predetermined threshold, an unacceptable charge transfer resistance R₁ state-of-health for the corresponding cell may be determined. In an embodiment, the constant cell currents may be constant charge currents, for example during a controlled charge routine through a vehicle charge port. Advantageously, a respective cell's coefficients a_{1,i} and a_{3,i} may effectively decouple or isolate charge transfer resistance R₁ of the cell from the cell's time constant τ=R₁C₁ under certain conditions.

FIG. 3 represents an exemplary direct current (DC) fast charge (FC) profile used in recharging an electric vehicle battery pack cell. Time in seconds (S) is plotted along the horizontal axis, cell terminal voltage (V) is plotted along the left-hand vertical axis, and current in amps (A) is plotted along the right-hand vertical axis. Current through the cell is represented by the broken trace and terminal voltage across the cell is represented by the solid trace. During an initial portion of the DCFC profile from about zero seconds to about 1750 seconds, charge current may be seen increasing from about 108 amps to just below about 150 amps. During this initial period, cell terminal voltage is seen increasing. After the initial portion of the DCFC profile, charge current is dropped to about 100 amps and remains constant during this subsequent period until about 3000 seconds whereafter charge current drops to a lower constant current. During this subsequent period, the cell terminal voltage may be seen increasing. Thus, from equation [2.6] it may be appreciated that the embodiments corresponding to constant current and solving for coefficients a_{0,i}, a_{1,i} and a_{3,i} may as set forth herein may advantageously be employed.

In an embodiment, cell currents I_{b} are zero. When the first predetermined threshold is exceeded by a respective cell's coefficient a_{1,i}, an unacceptable solid electrolyte interphase (SEI) layer state-of-health for the corresponding cell may be determined. From this information, the time constant τ=R₁C₁ of the corresponding cell is determined to correlate to an unacceptable solid electrolyte interphase (SEI) layer state-of-health.

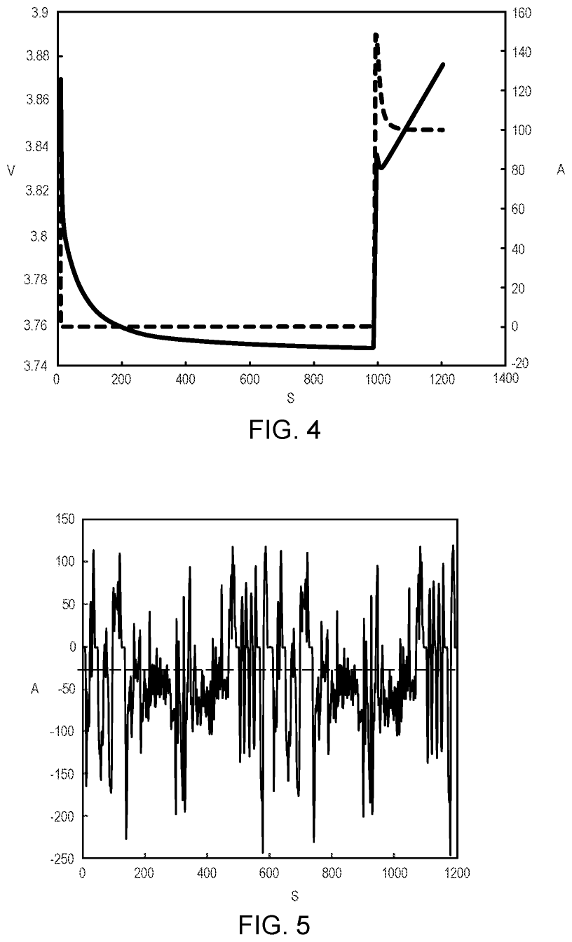

FIG. 4 represents an exemplary end-of-charge profile for a vehicle battery pack cell. Time (S) is plotted along the horizontal axis, cell terminal voltage (V) is plotted along the left-hand vertical axis, and current in amps (A) is plotted along the right-hand vertical axis. Current through the cell is represented by the broken trace and terminal voltage across the cell is represented by the solid trace. At time zero, a charging current through the cell drops to zero and the cell is shown relaxing for about 1000 seconds. During the relaxation, the cell terminal voltage may be seen decreasing, rapidly initially then asymptotically, following the constant τ=R₁C₁ of the cell. Thus, from equation [2.7] it may be appreciated that the embodiments corresponding to zero current and solving for coefficients a_{0,i} and a_{1,i} as set forth herein may advantageously be employed.

In an embodiment, a simplified model of the capacitance of a cell based on cell current metrics assumptions and constraints may be developed based on the Thevenin equivalent model equation [3] which may be rearranged to yield equation [3.1].

$${C}_{1} = \frac{- {V}_{1} / {R}_{1} + {I}_{b}}{{\dot{V}}_{1}} \qquad [ 3.1 ]$$

Assuming conditions of large İ_{b}, V₁/R₁ (i.e., the current through R₁) is negligible as most current flows through C₁ at large İ_{b}. Thus, V₁/R₁ may be dropped from equation [3.1] to yield the approximation of C₁ in equation [3.2].

$${C}_{1} \approx \frac{{I}_{b}}{{\dot{V}}_{1}} = \frac{{I}_{b}}{\frac{{d V}_{1}}{dt}} = \frac{{I}_{b} dt}{{d V}_{1}} \qquad [ 3.2 ]$$

The terminal voltage V_{T} is given by equation [1] as follows.

$${V}_{T} = {V}_{oc} + {R}_{o} {I}_{b} + {V}_{1} \qquad [ 1 ]$$

Differentiation of equation [1] with respect to time yields the differential equation [1.1].

$$\frac{{d V}_{T}}{dt} = \frac{{d V}_{OC}}{dt} + \frac{{R}_{O} {dI}_{b}}{dt} + \frac{{d V}_{1}}{dt} \qquad [ 1.1 ]$$

Because open circuit voltage changes very slowly (i.e., \dot{V}_{OC}<<\dot{V}₁ and \dot{V}_{OC}<<\dot{V}_{T}), \dot{V}_{OC} is negligible and dropped from equation [1.1] to yield equation [1.2].

$$\frac{{d V}_{T}}{dt} = \frac{{R}_{O} {dI}_{b}}{dt} + \frac{{d V}_{1}}{dt} \qquad [ 1.2 ]$$

### Substituting

$$\frac{{d V}_{1}}{dt}$$

from equation [1.2] into equation [3.2] yields equation [3.3].

$${C}_{1} \approx \frac{{I}_{b}}{\frac{{d V}_{1}}{dt}} = \frac{{I}_{b}}{\frac{{d V}_{T}}{dt} - \frac{{R}_{O} {dI}_{b}}{dt}} = \frac{{I}_{b} dt}{{d V}_{T} - {R}_{O} {dI}_{b}} \qquad [ 3.3 ]$$

Inverting equation [3.3] and separating terms yields equation [3.4].

$$\frac{1}{{C}_{1}} = \frac{{d V}_{T}}{{I}_{b} dt} - \frac{{dI}_{b}}{dt} \times \frac{{R}_{O}}{{I}_{b}} \qquad [ 3.4 ]$$

It is recognized that in the lithium-ion battery pack that the cells are series connected and thus the current I_{b} through the cells is equivalent and any change in current is also equivalent. Thus, any change in capacitance may be approximated by equation [3.5].

$$Δ {C}_{1} = \frac{{I}_{b} dt}{{d V}_{T}} = \frac{dQ}{{d V}_{T}} \qquad [ 3.5 ]$$

In equation [3.5], dQ is the change in charge, dV_{T} is the change in terminal voltage, and dt is the time interval during which the charge is transferred and over which the change in charge dQ and change in terminal voltage dV_{T} are determined.

In an embodiment, a lithium-ion battery pack may include multiple (n) cells connected in series. Each of the of the multiple (n) cells may be modeled in including the subscripted i accordance with equation [3.5]

$$Δ {C}_{1 , i} = \frac{{I}_{b} dt}{{d V}_{T , i}} = \frac{{dQ}_{, i}}{{d V}_{T , i}}$$

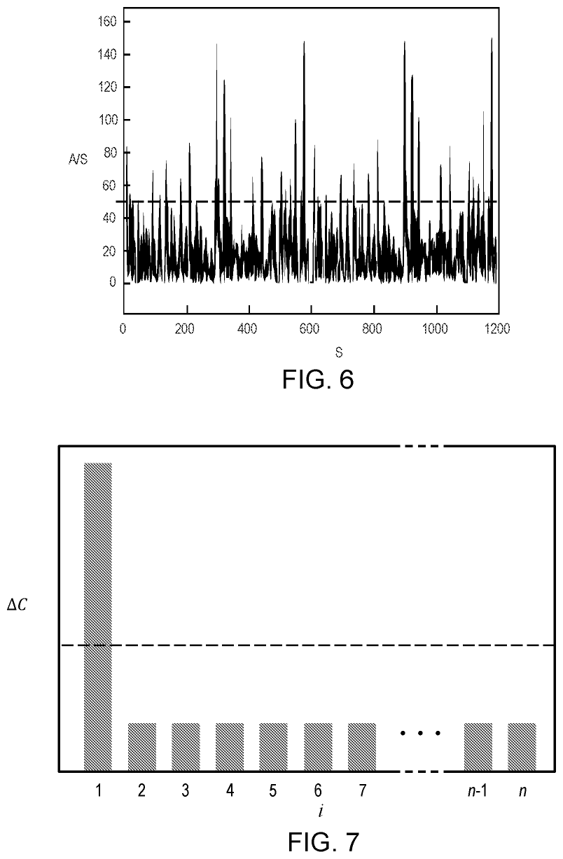

designation where i=1 to n. Advantageously, readily accessible voltage and current measurements, V_{T,i} and I_{b}, for the terminal voltages and the cell currents may provide the only parameters necessary for determining capacitance change ΔC_{1,i}. From terminal voltage measurements V_{T,i}, change in terminal voltage dV_{T} may be determined over a time interval such as a monitoring control cycle. Thus, in an embodiment, discharge current/p through the cells may be monitored. FIG. 5 illustrates an exemplary plot of cell current versus time in an operational electric vehicle during a typical drive cycle. Current in amps (A) is plotted along the vertical axis and time in seconds (S) is plotted along the horizontal axis. Positive currents correspond to cell charging (i.e., regenerative charging) while negative currents correspond to cell discharging (i.e., propulsion discharging). In an embodiment of a series connected plurality of cells, monitoring of the battery pack discharge current may provide the measure of discharge current through each cell and individual cell current measurements need not be taken. From the monitored discharge current, the rate of change of discharge current through each cell İ_{b} may be determined. FIG. 6 illustrates an exemplary plot of cell current rate of change versus time in an operational electric vehicle during a typical drive cycle corresponding to the exemplary plot of cell current versus time of FIG. 5. The absolute value of rate of change of current in amps with respect to time in seconds (A/S) is plotted along the vertical axis and time in seconds (S) is plotted along the horizontal axis. Monitoring of the terminal voltage across each cell also provides corresponding terminal voltage measurements V_{T,i}. The rate of change of discharge current through each cell/p may be compared to a predetermined rate of change threshold (e.g., |−50| amps/second) (broken line of FIG. 6) as one constraint or entry condition for the present model use. In an embodiment, a second constraint or entry condition may include discharge current magnitude and the discharge current I_{b} through the cells may be compared to a predetermined current magnitude threshold (e.g., −30 amps) (broken line of FIG. 5). When both thresholds are met, the ratio of a) the product of the discharge current over the time interval and the time interval to b) the change in the respective terminal voltage over the time interval may be determined. The ratio for each cell may be compared to a ratio threshold which if exceeded may indicate an unacceptable solid electrolyte interphase (SEI) layer state-of-health for the respective cell. This embodiment has been described with respect to discharge currents; however, it is understood that it is equally applicable to charge currents.

In an embodiment, the ratio threshold may simply be a calibration value. In an embodiment, the calibration value may be adapted throughout the life cycle of the battery pack to track normal SEI layer growth, for example to prevent undesirable false positive diagnosis. In an embodiment, the ratio threshold may be a value based upon the respective capacitance changes ΔC_{1,i} from a subset of the multiple (n) cells excluding the capacitance change ΔC_{1,i} from the cell presently being diagnosed. For example, a statistical representation of the capacitance change ΔC_{1,i} from such a subset may be used as the ratio threshold. Such statistical representation may take the form of a simple mean or median value or more sophisticated representations based on data distributions, probabilistic models and regressed data. For example, the ratio threshold may be represented as some multiple of a standard deviation of the capacitance changes ΔC_{1,i} from such a subset of the multiple (n) cells excluding the capacitance change ΔC_{1,i} from the cell presently being diagnosed. FIG. 7 illustrates relative magnitude of capacitance change ΔC along the vertical axis and cell number i=1 ton along the horizontal axis. Plotted are individual cell capacitance change ΔC_{1,i} and a threshold (broken line). For example, the cell being diagnosed may be cell 1 and the threshold may be determined as three standard deviations of the capacitance changes ΔC_{1,i} for the remaining cells i=2 to n.

In an embodiment, a simplified model of the time constant τ=R₁C₁ of a cell based on cell current metrics assumptions and constraints may be developed based on the Thevenin equivalent model equation [3] as follows.

$$τ = {R}_{1} {C}_{1} = \frac{{V}_{OC} - {V}_{T} + {R}_{O} {I}_{b} + {R}_{1} {I}_{b}}{{\dot{V}}_{1}} \qquad [ 3 ]$$

Assuming conditions of zero current subsequent to a charge period, equation [3] may be simplified by dropping the R_{O}I_{b}+R₁I_{b} terms which reduce to zero. Thus, equation [3] may be rewritten as equation [3.6].

$$τ = {R}_{1} {C}_{1} = \frac{{V}_{OC} - {V}_{T}}{{\dot{V}}_{1}} \qquad [ 3.6 ]$$

The voltage across the parallel R₁C₁ network V₁ is found in equation [1] as follows.

$${V}_{T} = {V}_{oc} + {R}_{o} {I}_{b} + {V}_{1} \qquad [ 1 ]$$

Taking derivatives of equation [1] yields equation [1.1].

$${\dot{V}}_{T} = {\dot{V}}_{OC} + {R}_{O} {\dot{I}}_{b} + {\dot{V}}_{1} \qquad [ 1.1 ]$$

Because open circuit voltage changes very slowly, \dot{V}_{OC}<<\dot{V}₁ and \dot{V}_{T}, \dot{V}_{OC} is negligible and equation [1.1] is closely approximated by equation [1.2].

$${\dot{V}}_{T} = {R}_{O} {\dot{I}}_{b} + {\dot{V}}_{1} \qquad [ 1.2 ]$$

Again assuming conditions of zero current subsequent to a charge period, equation [1.2] may be simplified by dropping the R_{O}İ_{b} term which reduces to zero. Thus, equation [1.2] may be rewritten as equation [1.3].

$${\dot{V}}_{T} = {\dot{V}}_{1} \qquad [ 1.3 ]$$

Substituting \dot{V}_{T} from equation [1.3] into equation [3.6] for \dot{V}₁ yields equation [3.7].

$$τ = {R}_{1} {C}_{1} = \frac{{V}_{OC} - {V}_{T}}{{\dot{V}}_{T}} \qquad [ 3.6 ]$$

In an embodiment, a lithium-ion battery pack may include multiple (n) cells connected in series. Each of the of the multiple (n) cells may be modeled in accordance with equation [3.6]

$${τ}_{i} = {R}_{1 , i} {C}_{1 , i} = \frac{{V}_{OC , i} - {V}_{T , i}}{{\dot{V}}_{T , i}}$$

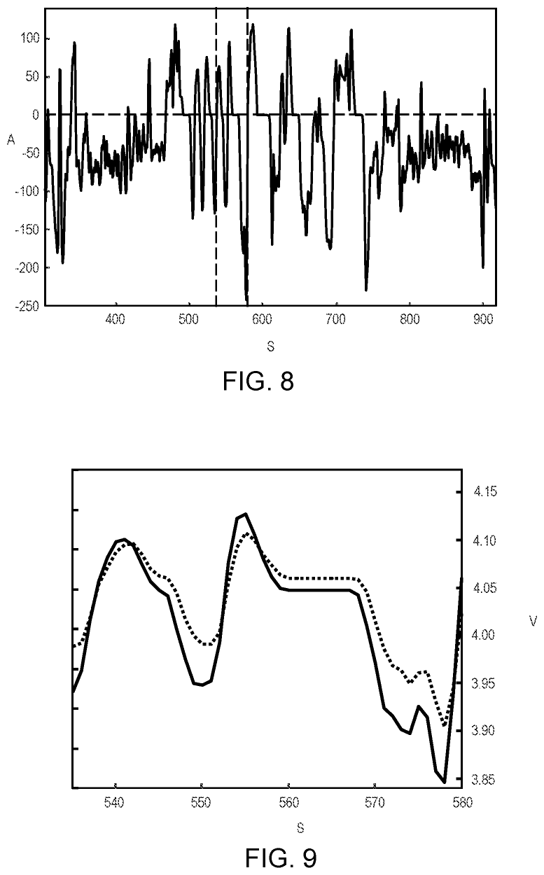

including the subscripted i designation where i=1 to n. Advantageously, readily accessible voltage measurements and estimations, V_{T,i} and V_{OC,i}, for the terminal voltages and the open circuit voltage may provide the only parameters necessary for determining the cell time constant τᵢ=R_{1,i}C_{1,i}. From terminal voltage measurements V_{T,i}, rate of change in terminal voltage \dot{V}_{T,i} may be determined over a time interval such as a monitoring control cycle. Thus, in an embodiment current through the battery pack may be measured and respective terminal voltage across each cell may be measured. Open circuit voltage for each cell may be monitored and provided from estimations. When the battery pack is in a relaxation period of zero current through the battery pack after a charging period, a respective rate of change in terminal voltage \dot{V}_{T,i} and a respective voltage difference between the respective open circuit voltage and respective terminal voltage for each cell may be determined. FIG. 8 illustrates an exemplary plot of cell current versus time in an operational electric vehicle during a typical drive cycle. Current in amps (A) is plotted along the vertical axis and time in seconds(S) is plotted along the horizontal axis. Positive currents correspond to cell charging (i.e., regenerative charging) while negative currents correspond to cell discharging (i.e., propulsion discharging). FIG. 9 illustrates an exemplary plot of voltage versus time in an operational electric vehicle during a typical drive cycle corresponding to the exemplary plot of cell current versus time of FIG. 8. Voltage (Volts) is plotted along the vertical axis and time in seconds (S) is plotted along the horizontal axis. The terminal voltage \dot{V}_{T,i} corresponds to the solid trace whereas the open circuit voltage V_{OC,i} corresponds to the broken trace. A respective time constant for each cell may be determined as the ratio of the respective voltage difference and the respective rate of change in terminal voltage. The time constant for each cell may be compared to a time constant threshold which if exceeded may indicate an unacceptable solid electrolyte interphase (SEI) layer state-of-health for the respective cell.

In an embodiment, the time constant threshold may simply be a calibration value. In an embodiment, the calibration value may be adapted throughout the life cycle of the battery pack to track normal SEI layer growth, for example to prevent undesirable false positive diagnosis. In an embodiment, the ratio threshold may be a value based upon the respective time constants τᵢ=R_{1,i}C_{1,i} from a subset of the multiple (n) cells excluding the time constants τᵢ=R_{1,i}C_{1,i} from the cell presently being diagnosed. For example, a statistical representation of the time constants τᵢ=R_{1,i}C_{1,i} from such a subset may be used as the ratio threshold. Such statistical representation may take the form of a simple mean or median value or more sophisticated representations based on data distributions, probabilistic models and regressed data. For example, the time constant threshold may be represented as some multiple of a standard deviation of the time constants τᵢ=R_{1,i}C_{1,i} from such a subset of the multiple (n) cells excluding the time constant τᵢ=R_{1,i}C_{1,i} from the cell presently being diagnosed.

The terminology used herein is for the purpose of describing particular embodiments only and is not intended to be limiting. The terms “a” and “an” do not denote a limitation of quantity, but rather denote the presence of at least one of the referenced items. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

All numeric values herein are assumed to be modified by the term “about” whether or not explicitly indicated. For the purposes of the present disclosure, ranges may be expressed as from “about” one particular value to “about” another particular value. The term “about” generally refers to a range of numeric values that one of skill in the art would consider equivalent to the recited numeric value, having the same function or result, or reasonably within manufacturing tolerances of the recited numeric value generally. Similarly, numeric values set forth herein are by way of non-limiting example and may be nominal values, it being understood that actual values may vary from nominal values in accordance with environment, design and manufacturing tolerance, age and other factors.

When an element such as a layer, film, region, or substrate is referred to as being “on” another element, it can be directly on the other element or intervening elements may also be present. In contrast, when an element is referred to as being “directly on” another element, there are no intervening elements present. Therefore, unless explicitly described as being “direct,” when a relationship between first and second elements is described in the above disclosure, that relationship may be a direct relationship where no other intervening elements are present between the first and second elements but may also be an indirect relationship where one or more intervening elements are present (either spatially or functionally) between the first and second elements.

One or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Unless defined otherwise, technical and scientific terms used herein have the same meaning as is commonly understood by one of skill in the art to which this disclosure belongs.

Unless specified to the contrary herein, all test standards are the most recent standard in effect as of the filing date of this application, or, if priority is claimed, the filing date of the earliest priority application in which the test standard appears.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method of determining a state-of-health of each cell in a lithium-ion battery pack of multiple (n) cells, comprising:
modeling each of the multiple (n) cells in accordance with a relationship V_{T,i}=a_{0,i}−a_{1,i}\dot{V}_{T,i}+a_{2,i}İ_{b}+a_{3,i}I_{b} for i=1 ton wherein
V_{T,i} is a terminal voltage of the ith cell,
\dot{V}_{T,i} is a time derivative of the terminal voltage of the ith cell,
I_{b} is a current through the ith cell,
İ_{b} is a time derivative of the current through the ith cell,
a_{0,i} is V_{OC,i}, wherein V_{OC,i} is an open circuit voltage of a Thevenin equivalent of the ith cell,
a_{1,i} is R_{1,i}C_{1,i}, wherein R_{1,i} is a charge transfer resistance of the Thevenin equivalent of the ith cell and C_{1,i} is a capacitance of the Thevenin equivalent of the ith cell in parallel with R_{1,i},
a_{2,i} is R_{O,i}R_{1,i}C_{1,i}, wherein R_{O,i} is an internal resistance of the Thevenin equivalent of the ith cell, and
a_{3,i} is R_{O,i}+R_{1,i} for the ith cell;
periodically measuring V_{T,i} and I_{b} for each of the multiple (n) cells;
estimating \dot{V}_{T,i} and İ_{b} based on V_{T,i} and I_{b} for each of the multiple (n) cells;
estimating a_{0,i}, a_{1,i}, a_{2,i} and a_{3,i} for each of the multiple (n) cells based on the relationship V_{T,i}=a_{0,i}−a_{1,i}\dot{V}_{T,i}+a_{2,i}İ_{b}+a_{3,i}I_{b};
determining if a_{1,i} for each of the multiple (n) cells exceeds a first predetermined threshold; and
diagnosing an unacceptable solid electrolyte interphase (SEI) layer state-of-health for the ith cell when a_{1,i} for the ith cell exceeds the first predetermined threshold.

2. The method of claim 1 wherein the first predetermined threshold comprises a calibration value.

3. The method of claim 1 wherein the first predetermined threshold comprises a value based upon the respective a_{1,i} from a subset of the multiple (n) cells excluding the ith cell.

4. The method of claim 1 further comprising diagnosing an unacceptable internal resistance state-of-health for the respective cell when a_{1,i} does not exceed the first predetermined threshold and a_{2,i} exceeds a second predetermined threshold.

5. The method of claim 1 further comprising diagnosing an unacceptable internal resistance state-of-health for the respective cell when a_{1,i} does not exceed the first predetermined threshold and a_{3,i} exceeds a third predetermined threshold.

6. The method of claim 1 further comprising diagnosing an unacceptable internal resistance state-of-health for the respective cell when a_{1,i} does not exceed the first predetermined threshold, a₂ exceeds a second predetermined threshold and a_{3,i} exceeds a third predetermined threshold.

7. The method of claim 1 wherein the method is carried out under a constant current constraint, further comprising diagnosing an unacceptable cell capacitance state-of-health for the respective cell when a_{3,i} does not exceed a third predetermined threshold.

8. The method of claim 1 wherein the method is carried out under a constant current constraint, further comprising diagnosing an unacceptable charge transfer resistance state-of-health for the respective cell when a_{3,i} exceeds a third predetermined threshold.

9. The method of claim 1 wherein the method is carried out under a zero current constraint.

10. The method of claim 7 wherein the constant current constraint comprises a constant charge current.

11. The method of claim 8 wherein the constant current constraint comprises a constant charge current.

12. The method of claim 1 wherein estimating a_{0,i}, a_{1,i}, a_{2,i} and a_{3,i} for each of the multiple (n) cells based on the relationship V_{T,i}=a_{0,i}−a_{1,i}\dot{V}_{T,i}+a_{2,i}İ_{b}+a_{3,i}I_{b} comprises performing a recursive least squares estimation.

13. A method of determining a state-of-health of each cell in a lithium-ion battery pack of multiple (n) cells connected in series, comprising:
monitoring a current through the battery pack;
monitoring a respective terminal voltage across each cell;
determining a rate of change of the current;
when the rate of change of the current exceeds a predetermined rate of change threshold and the current exceeds a predetermined current threshold, determining for each cell a ratio of a) the product of the current over a time interval and the time interval to b) a change in the respective terminal voltage over the time interval;
determining if the ratio for each cell exceeds a predetermined ratio threshold; and
diagnosing an unacceptable solid electrolyte interphase (SEI) layer state-of-health for one respective cell when the ratio for the one respective cell exceeds the predetermined threshold.

14. The method of claim 13 wherein the predetermined threshold comprises a calibration value.

15. The method of claim 13 wherein the predetermined threshold comprises a value based upon the respective ratios from a subset of the multiple (n) cells excluding the one respective cell.

16. A method of determining a state-of-health of each cell in a lithium-ion battery pack of multiple (n) cells connected in series, comprising:
monitoring current through the battery pack;
monitoring a respective terminal voltage across each cell;
monitoring a respective open circuit voltage for each cell; and
when the battery pack is in a relaxation period after a charging period wherein the relaxation period includes zero current through the battery pack,
determining for each of the multiple (n) cells a respective time rate of change of the respective terminal voltage,
determining for each of the multiple (n) cells a respective voltage difference between the respective open circuit voltage and respective terminal voltage,
determining a respective time constant for each of the multiple (n) cells as a ratio of the respective voltage difference and the respective time rate of change,
determining if the respective time constant for each of the multiple (n) cells exceeds a predetermined time constant threshold, and
diagnosing an unacceptable solid electrolyte interphase (SEI) layer state-of-health for one respective cell when the respective time constant for the one respective cell exceeds the predetermined time constant threshold.

17. The method of claim 16 wherein the predetermined threshold comprises a calibration value.

18. The method of claim 16 wherein the predetermined threshold comprises a value based upon the respective ratios from a subset of the multiple (n) cells excluding the one respective cell.

19. The method of claim 16 wherein the method is carried out during a vehicle drive cycle.

20. The method of claim 19 wherein the charging period comprises a regenerative braking period.
